(19) United States
(12) Patent Application Publication
(10) Pub. No.: US 2004/0008499 A1
(43) Pub. Date: Jan. 15, 2004

(54) Filter

(75) Inventor: Chien Yee Chiang, Taoyuan Hsien (TW)

Correspondence Address: BRUCE H. TROXELL, SUITE 1404, 5205 LEESBURG PIKE, FALLS CHURCH, VA, 22041, US

(73) Assignee: Ferrico Corporation

(21) Appl. No.: 10/617,378

(22) Filed: Jul. 11, 2003

(30) Foreign Application Priority Data
Jul. 12, 2002 (TW) 091210659

(51) Int. Cl. H05K 7/14; H05K 7/18

(52) U.S. Cl. 361/797

(57) ABSTRACT

A filter for removing electric noises from an electric wire is disclosed to include an electrically insulative hollow cylindrical casing formed of two symmetric half shells joined by flexible hinge strips and detachably locked by a fastening device, each half shell having two notched end walls and a male locating device, and two magnetic core members mounted inside the casing and abutted against each other to hold an electric wire in therebetween, each magnetic core member having a longitudinally extended recessed portion located on the inside wall to accommodate the electric wire and a female locating device for receiving the male locating devices of the half shells of the casing.

### BACKGROUND OF THE INVENTION

1. Field of the Invention

The present invention relates to an electric filter for use in an electric circuit to remote electric noises and, more particularly, to a simple structure of filter, which is easy and inexpensive to manufacture.

2. Description of the Related Art

A filter used in an electric circuit in an electronic apparatus, for example, a computer, is adapted to remove electric noises. A regular filter for this purpose is comprised of a magnetic core, which has a center through hole for the passing of an electric wire, and a cover shell covering the magnetic core. The magnetic core is comprised of two symmetrical half core elements shaped like a semicircular tube. The cover shell fits the outer diameter of the magnetic core. Similar designs are seen in Japanese Patent Nos. 2938446, 2801173, 2774454, and Taiwan Patent No. 2787747 entitled “Filtering Clip”. These conventional designs are commonly complicated, resulting in a high manufacturing cost.

### SUMMARY OF THE INVENTION

The present invention has been accomplished under the circumstances in view. It is the main object of the present invention to provide a filter for use in an electric circuit to remote electric noises, which is inexpensive to manufacture. It is another object of the present invention to provide a filter for use in an electric circuit to remote electric noses, which is easy to install.

To achieve these and other objects of the present invention, the filter comprises an electrically insulative hollow cylindrical casing, the casing comprising two symmetric half shells, flexible hinge means connected between the half shells, and a fastening device formed in the half shells and adapted to lock the half shells to each other in a closed status, the half shells each having two end walls and a locating device, the end walls each having a notch for the passing of an electric wire; and two magnetic core members mounted inside the casing and abutted against each other and adapted to hold an electric wire in therebetween, the magnetic core members each having a longitudinally extended recessed portion located on an inside wall thereof and adapted to accommodate an electric wire and a locating device for receiving the locating devices of the half shells of the casing.

### BRIEF DESCRIPTION OF THE DRAWINGS

FIG. 1 is an exploded view of a filter according to the first embodiment of the present invention.

FIG. 2 is an elevational assembly view of the filter according to the first embodiment of the present invention.

FIG. 3 is an exploded view of a filter according to the second embodiment of the present invention.

FIG. 4 is an exploded view of a filter according to the third embodiment of the present invention.

### DETAILED DESCRIPTION OF THE PREFERRED EMBODIMENT

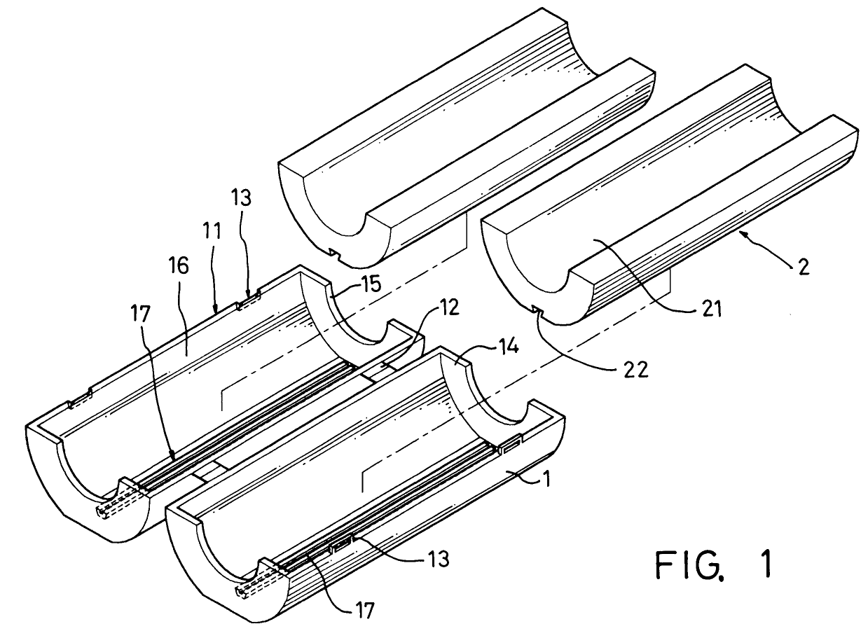

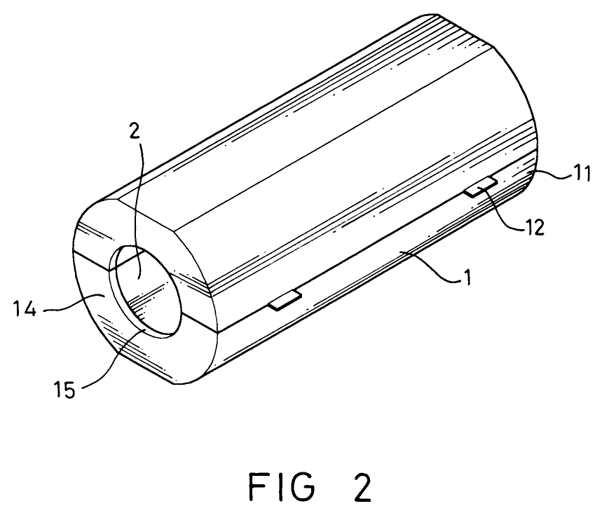

Referring to FIGS. 1 and 2, a filter in accordance with the first embodiment of the present invention is shown comprised of a hollow cylindrical casing 1, and yep magnetic core members 2 mounted in the casing 1.

The hollow cylindrical casing 1 is injection-molded from electrically insulative plastics, comprising two symmetric half shells 11 of semicircular cross-section, at least one, for example, two flexible hinge strips 12 connected between the half shells 11, and a fastening device 13 formed in the half shells 11 and adapted to lock the half shells 11 to each other in a closed status. The fastening device 13 may be variously embodied. For example, the fastening device 13 is comprised of a plurality of retaining grooves respectively formed in one half shell of the casing 1, and a plurality of retaining flanges respectively formed in the other half shell of the casing 1 for engaging the retaining grooves. The half shells 11 each have two end walls 14. The end walls 14 each have a smoothly arched notch 15. The end walls 14 define with the periphery of the respective shell 11 a receiving open chamber 16. Each shell 11 further comprises a male locating device, for example, a locating rib 17 longitudinally located on the inside of the receiving open chamber 16.

The magnetic core members 2 are symmetrical and shaped like a semicircular tube fitting the receiving open chamber 16, each having a recessed portion 21 of semicircular cross-section located on the inside wall and longitudinally extended to the two distal ends, and a female locating device, for example, a locating groove 22 longitudinally located on the outside wall for receiving the locating rib 17 in the receiving open chamber 16 of the corresponding shell 11.

Before use, the magnetic core members 2 are respectively mounted the receiving open chambers 16 of the half shells 11 of the casing 1, keeping the locating grooves 22 of the magnetic core elements 21 in engagement with the locating ribs 17 of the half shells 11 of the casing 1.

During installation, the electric wire is axially set the recessed portion 21 of one (the first) magnetic core member 2 in one (the first) half shell 11 of the casing 1, and then the other (second) magnetic core member 2 is closed with the other (second) half shell 11 on the first magnetic core member 2 and the first half shell 11 to hold down the electric wire.

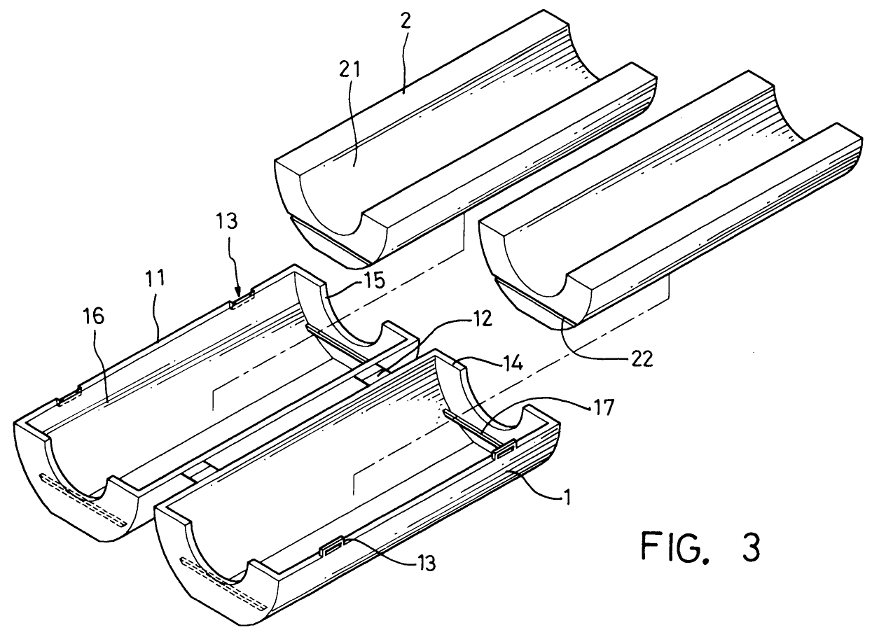

FIG. 3 is an exploded view of a filter according to the second embodiment of the present invention. This embodiment is similar to the aforesaid first embodiment with the exception of the arrangement of the male locating devices 17 and the female locating devices 22. According to this embodiment, the male locating device 17 of each half shell 11 of the casing 1 is comprised of two locating ribs respectively transversely formed in the end walls 14 inside the respective half shell 11; the female locating device 22 of each magnetic core member 2 is comprised of two locating grooves respectively transversely formed in the two ends.

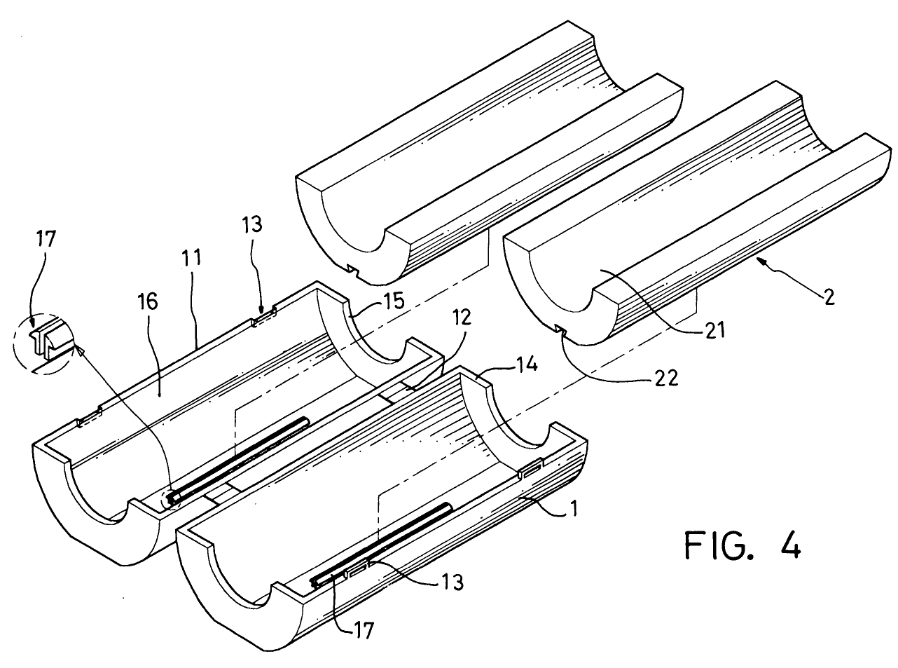

FIG. 4 is an exploded view of a filter according to the third embodiment of the present invention. This embodiment is similar to the aforesaid first embodiment with the exception of the arrangement of the male locating devices 17 and the female locating devices 22. According to this embodiment, the male locating device 17 of each half shell 11 of the casing 1 is comprised of two locating ribs of substantially angled cross-section longitudinally located on the inside of the receiving open chamber 16 and arranged in parallel; the female locating device 22 of each magnetic core member 2 is comprised of a locating groove of T-shaped cross-section longitudinally located on the outside wall of the respective magnetic core member 2 for receiving the locating ribs 17 in the receiving open chamber 16 of the corresponding shell 11.

A prototype of filter has been constructed with the features of FIGS. 1˜4. The filter functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A filter comprising:
an electrically insulative hollow cylindrical casing, said casing comprising two symmetric half shells, flexible hinge means connected between said half shells, and a fastening device formed in said half shells and adapted to lock said half shells to each other in a closed status, said half shells each having two end walls and a locating device, said end walls each having a notch for the passing of an electric wire; and
two magnetic core members mounted inside said casing and abutted against each other and adapted to hold an electric wire in therebetween, said magnetic core members each having a longitudinally extended recessed portion located on an inside wall thereof and adapted to accommodate an electric wire and a locating device for receiving the locating devices of said half shells of said casing.

2. The filter as claimed in claim 1, wherein said half shells of said casing and said magnetic core members have a semicircular cross-section.

3. The filter as claimed in claim 1, wherein said fastening device of said casing is comprised of a plurality of female fastening elements formed in one half shell of said casing, and a plurality of male fastening elements formed in the other half shell of said casing and adapted to engage said female fastening elements.

4. The filter as claimed in claim 1, wherein the locating device of each half shell of said casing is comprised of at least one locating rib; the locating device of each of said magnetic core members is comprised of at least one locating groove adapted to receive the at least one locating rib of each of the half shells of said casing.

5. The filter as claimed in claim 1, wherein the locating device of each half shell of said casing is comprised of a longitudinal rib longitudinally formed in an inside wall thereof between the respective two end walls; the locating device of each of said magnetic core members is comprised of a longitudinal groove formed in a peripheral wall thereof for receiving the longitudinal rib of one half shell of said casing.

6. The filter as claimed in claim 1, wherein the locating device of each half shell of said casing is comprised of two transverse ribs transversely formed in the respective end walls at an inner side; the locating device of each of said magnetic core members is comprised of two transverse grooves respectively formed in two distal ends thereof for receiving the transverse ribs of one half shell of said casing.

7. The filter as claimed in claim 1, wherein the locating device of each half shell of said casing is comprised of two angled locating ribs symmetrically and longitudinally arranged in parallel on an inside wall thereof; the locating device of each of said magnetic core members is comprised of a locating groove having a T-shaped cross-section and longitudinally located on an outside wall thereof for receiving the angled locating ribs of one half shell of said casing.
